(19) United States
(12) Patent Application Publication
(10) Pub. No.: US 2026/0009765 A1
(43) Pub. Date: Jan. 8, 2026

(54) Inspection Device

(71) Applicants: Hitachi, Ltd., Chiyoda-ku, Tokyo (JP); Institute of Science Tokyo, Meguro-ku, Tokyo (JP)

(72) Inventors: Teruo KOHASHI, Tokyo (JP); Masanari KOGUCHI, Tokyo (JP); Toshiaki TANIGAKI, Tokyo (JP); Ryota KITAGAWA, Tokyo (JP); Mutsuko HATANO, Tokyo (JP)

(21) Appl. No.: 18/993,062

(22) PCT Filed: Aug. 1, 2022
(86) PCT No.: PCT/JP2022/029451

§ 371 Date: Jan. 10, 2025

(51) Int. Cl. G01N 27/72; G01R 33/032

(52) U.S. Cl. CPC G01N 27/72; G01R 33/032

(57) ABSTRACT

Magnetism of each layer of two magnetic layers having different coercive forces and forming a magnetic tunnel junction of a memory cell of an MRAM is inspected with high accuracy in a state of being covered with a nonmagnetic body before wiring. An inspection device includes: an NVC probe in which diamond having an NVC is set at a tip, the NVC being a composite impurity defect formed of a pair of nitrogen substituting for carbon in a diamond lattice and a vacancy from where a carbon atom adjacent to the substitution nitrogen is removed; and a pulse magnetic field applying unit. The pulse magnetic field applying unit executes an applying step of applying a pulse magnetic field to a magnetic body in a sample, and the NVC probe executes a detection step of detecting a magnetic field from the magnetic body when application of the pulse magnetic field by the pulse magnetic field applying unit is stopped.

### TECHNICAL FIELD

The present disclosure relates to an inspection device, and more particularly, to a scanning probe microscope having a function of an inspection device for inspecting a magnetic memory, or a semiconductor inspection device for inspecting a magnetic memory.

### BACKGROUND ART

There has been an interest in a measurement method using a nitrogen-lattice defect (vacancy) pair (Nitrogen-Vacancy-Center: NVC) contained in diamond. The NVC is referred to as a nitrogen-vacancy center, a nitrogen vacancy center, an NV center, or the like. Here, the method utilizes the fact that in a diamond crystal, a site in which carbon is substituted by nitrogen and a vacancy are adjacent to each other, and a characteristic electronic level is formed at the vacancy (for example, PTL 1). It is known that a fine electronic level can be used even at a room temperature, and in particular, a high-sensitivity measurement can be performed in a magnetic field. Further, by adjusting a crystal axis direction, the magnetic field can be detected in a three-dimensional manner for each direction component. A scanning probe microscope using a diamond microcrystal having an NVC as a probe is also developed and reports a magnetic domain observation such as Skyrmion. At present, the technology is used for a purpose of investigating basic physical properties.

In a magnetic evaluation of a minute region of 100 nm or less, a spin-polarized scanning electron microscope (spin SEM) is proposed (for example, PTL 2).

### CITATION LIST

### Patent Literature

PTL 1: JP2021-152473A

PTL 2: JP2011-059057A

### SUMMARY OF INVENTION

### Technical Problem

A memory cell of a magneto-resistive-random access memory (MRAM), which is studied and developed as a next generation memory, uses a fact that a resistance between two magnetic thin films (magnetic layers) formed with an insulating layer interposed therebetween changes according to magnetization directions of the magnetic layers (referred to as a tunnel magneto-resistive effect). In a manufacturing process of the MRAM, damage to magnetism of the magnetic layer particularly during etching is an important problem, and it is said that if magnetism of a minute region of each magnetic layer can be evaluated after the etching is completed, development of the MRAM device is remarkably accelerated. However, under present circumstances, a state of the magnetic layer of the MRAM cannot be known unless a wiring to the memory cell of the MRAM is completed and the tunnel magneto-resistive effect is verified. Accordingly, there is a demand for a method of inspecting the state of the two magnetic layers in the MRAM with high accuracy in a state of being covered with a nonmagnetic body before wiring.

### Solution to Problem

An outline of a typical aspect according to the present disclosure will be briefly described below.

According to an aspect of the present disclosure, an inspection device includes: an NVC probe in which diamond having an NVC is set at a tip, the NVC being a composite impurity defect formed of a pair of nitrogen substituting carbon in a diamond lattice and a vacancy from where a carbon atom adjacent to the substitution nitrogen is removed; and a pulse magnetic field applying unit. The pulse magnetic field applying unit executes an applying step of applying a pulse magnetic field to a magnetic body in a sample, and the NVC probe executes a detection step of detecting a magnetic field from the magnetic body when application of the pulse magnetic field by the pulse magnetic field applying unit is stopped.

### Advantageous Effects of Invention

According to the inspection device according to an aspect of the present disclosure, magnetism of each layer of a two-layer magnetic body (magnetic layers) having different coercive forces constituting a magnetic tunnel junction of a memory cell of an MRAM can be inspected with high accuracy in a state of being covered with a nonmagnetic body before wiring.

### BRIEF DESCRIPTION OF DRAWINGS

FIG. 1 shows a magnetization inspection principle of a magnetic body covered with a nonmagnetic body using an NVC probe according to an embodiment.

FIG. 2 shows a measurement principle when a pulse magnetic field is used in a magnetic body inspection using the NVC probe according to the embodiment.

FIG. 3 shows an overall configuration of an inspection device according to Embodiment 1.

FIG. 4 shows a flowchart of an inspection according to Embodiment 1.

FIG. 5 shows data acquired in the inspection according to Embodiment 1 and an analysis example.

FIG. 6 shows an example of a display screen of a control device according to Embodiment 1. Here, a list of results at a large number of inspection points is shown.

FIG. 7 shows an example of the display screen of the control device according to Embodiment 1. Here, an example of displaying detailed analysis results at a small number of inspection points is shown.

FIG. 8a shows, in the inspection device according to Embodiment 1, an example of a mesh at the time of magnetic field reconstruction of a MTJ, and shows an example of dividing a bottom surface into concentric shapes.

FIG. 8b shows, in the inspection device according to Embodiment 1, an example of the mesh at the time of the magnetic field reconstruction of the MTJ, and shows an example of dividing a bottom surface into sectors with equal interior angles from a center.

FIG. 8c shows an example of the mesh at the time of the magnetic field reconstruction of the MTJ, and shows an example in which the concentric circles in FIG. 8a and the sectors divided at equal interior angles from the center in FIG. 8b are combined.

FIG. 9 shows, in an inspection device according to Embodiment 2, an example of an inspection device in which a plurality of NVC probes are mounted in an array and a microwave antenna is shared by the plurality of probes.

FIG. 10 shows time dependence of power supplied to a pulse magnetic field applying coil and the microwave antenna in an inspection device according to Embodiment 3.

### DESCRIPTION OF EMBODIMENTS

Hereinafter, embodiments and examples will be described with reference to the drawings. However, in the following description, the same components are denoted by the same reference signs, and repeated description thereof may be omitted. It should be noted that the drawings may be more schematically illustrated than actual aspects in order to clarify the description, but are merely examples and do not limit the interpretation of the present disclosure.

### EMBODIMENTS

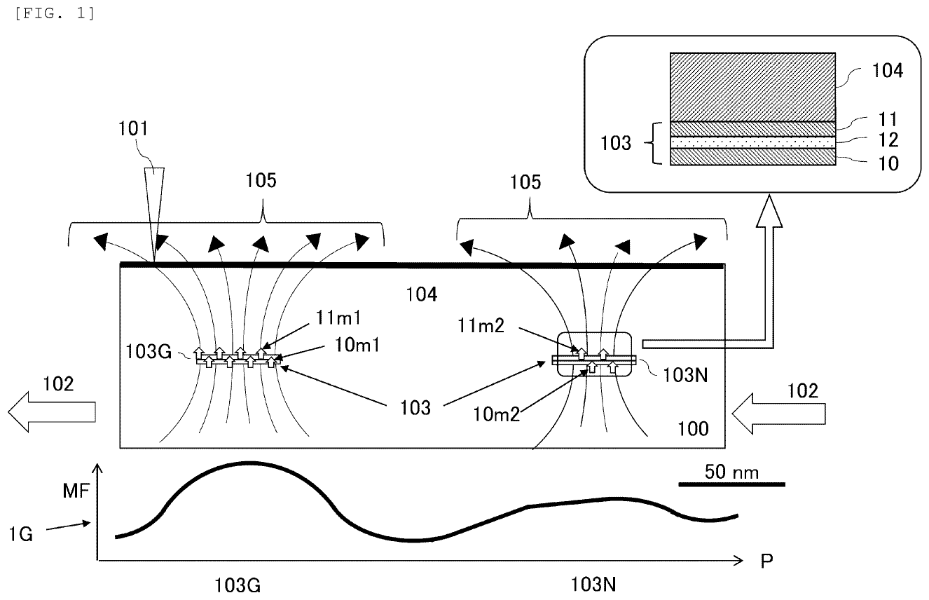

FIG. 1 is a diagram showing a measurement principle in an inspection device according to the present disclosure, and shows a magnetization inspection principle of a magnetic body covered with a nonmagnetic body using an NVC probe according to an embodiment.

In a process of manufacturing a memory such as a magneto-resistive-random access memory (MRAM), a situation in which a wafer 100 as a sample moves in a movement direction 102 immediately below an NVC probe 101 is considered. The NVC probe 101 is a probe in which diamond having a nitrogen vacancy center (NVC) is set at a tip. NVC is a composite impurity defect formed of a pair of nitrogen substituting for carbon in a diamond lattice and a vacancy from where a carbon atom adjacent to the substitution nitrogen is removed.

As shown in an enlarged manner in FIG. 1, in the wafer 100, two magnetic layers 10 and 11 each having, for example, a diameter of about several tens of nanometers in a plan view and a thickness of about 1 nm to 2 nm in a cross-sectional view are formed with an insulator 12 such as magnesium oxide (MgO) having a thickness of about 1 nm interposed therebetween. The magnetic layers 10 and 11 are magnetic layers having different coercive forces. These layers (10, 12, and 11) are referred to as a magnetic tunnel junction (MTJ) 103 of a memory cell of the MRAM. In FIG. 1, a state after an etching process is completed is assumed, and thus a nonmagnetic layer 104 made of tantalum (Ta) or the like of several tens of nanometers is formed on the MTJ 103. In the state where this etching process is completed, magnetization of the magnetic layers 10 and 11 of the MTJ 103 may be damaged, and if the magnetization of the magnetic layers 10 and 11 of the MTJ 103 can be inspected at this time point, an inspection of the etching process and verification of manufacturing conditions of the MTJ 103 can be immediately performed. However, it is currently difficult to inspect the magnetization of the magnetic layers 10 and 11 of the MTJ 103 at this time point. Therefore, at present, the magnetization of the magnetic layers 10 and 11 of the MTJ 103 is inspected by actually trying an operation of a memory of the MRAM in a state where a wiring to the memory cell of the MRAM is completed.

In a magnetic evaluation of a minute region having 100 nm or less, a spin-polarized scanning electron microscope (spin SEM) (for example, PTL 2) is used in practical applications such as observation of recording bits of hard disks. However, since a depth of a probe (probing depth) is as shallow as about 1 nm, this method cannot perform the evaluation unless the magnetic layer is exposed on a surface. In the MRAM, as shown in FIG. 1, the nonmagnetic layer 104 such as the Ta layer is stacked on an upper layer of the magnetic layer 11 to several tens of nm, and then etching is performed. Therefore, there is a problem that it is difficult to directly observe the magnetic layers 10 and 11 using the spin SEM after the etching. Since a magnetic force microscope (MFM) detects a leakage magnetic field from the sample, it is not necessary to expose a magnetic body. However, even in this method of detecting a magnetic field gradient, a signal becomes weak when a distance from a surface of the magnetic body is several tens of nanometers. The problem that it is difficult to inspect the magnetization of the magnetic layers 10 and 11 of the MTJ 103 also exists in this case.

In the inspection method of the present disclosure, the probe 101 on which the NVC capable of quantitatively detecting a minute magnetic field is mounted is used for the inspection. When the NVC probe 101 capable of detecting a magnetic field with good sensitivity is used, it is possible to detect a magnetic field (leakage magnetic field) 105 leaking from a surface of the wafer 100 even via the nonmagnetic body 104 of several tens nm as shown in FIG. 1. One of the MTJ 103 in the wafer 100 of the MRAM is set immediately below the probe 101, and magnetic force lines of a leakage magnetic field 105 leaking therefrom are detected while moving the wafer 100 in the movement direction 102. For example, when the MTJ 103 has large magnetization as designed or magnetization directions of the layers 10 and 11 are aligned (the magnetization directions are the same) (an MTJ 103G which is a normal good product), the leakage magnetic field 105 leaking onto the surface has a large value detected in a relatively wide region as shown on a left side of FIG. 1 (see MTJ 103G). On the other hand, when the magnetization of the magnetic layers 10 and 11 is damaged as shown on a right side of FIG. 1 (an MTJ 103N which is a defective product (bad product)), a range in which the leakage magnetic field 105 of the MTJ 103N is detected is narrow and small. In the MTJ 103 shown in FIG. 1, the magnetization directions from an N pole to an S pole of the magnetic layers 10 and 11 are indicated by arrows 10m1, 11m1, 10m2, and 11m2. In the case of the MTJ 103G as the normal good product, in this example, the magnetization direction and a magnetization amount of the magnetic layer 10 of the MTJ 103G are indicated by the four upward arrows 10m1, and the magnetization direction and a magnetization amount of the magnetic layer 11 of the MTJ 103G are indicated by the four upward arrows 11m1. On the other hand, in the case of the MTJ 103N as the defective product (bad product), the magnetization direction and a magnetization amount of the magnetic layer 10 of the MTJ 103N are indicated by the two upward arrows 10m2, and the magnetization direction and a magnetization amount of the magnetic layer 11 of the MTJ 103N are indicated by the two upward arrows 11m2 in this example. The magnetization directions and the magnetization amounts of the magnetic layers 10 and 11 of the MTJ 103N are smaller than the magnetization directions and the magnetization amounts of the magnetic layers 10 and 11 of the MTJ 103G. In particular, magnetization of peripheral portions of the magnetic layers 10 and 11 of the MTJ 103N is smaller than that of the magnetic layers 10 and 11 of the MTJ 103G, and at least the magnetization of the peripheral portions of the magnetic layers 10 and 11 of the MTJ 103N is in a damaged state.

A graph 1G on a lower side of FIG. 1 shows a relationship between a detected magnetic field MF and a position P. Here, a horizontal axis represents the position P, and a vertical axis represents the detected magnetic field MF in a vertical direction of the surface of the sample. Since shapes of created graphs (shape of the detected magnetic field EF) in the case of the normal good product MTJ 103G and the case of the damaged defective product (bad product) MTJ 103N are different, the good product and the defective product (bad product) of the magnetic layers 10 and 11 constituting the MTJ 103 of the MRAM can be inspected relatively accurately by accurately measuring such a leakage magnetic field 105 using the NVC probe 101.

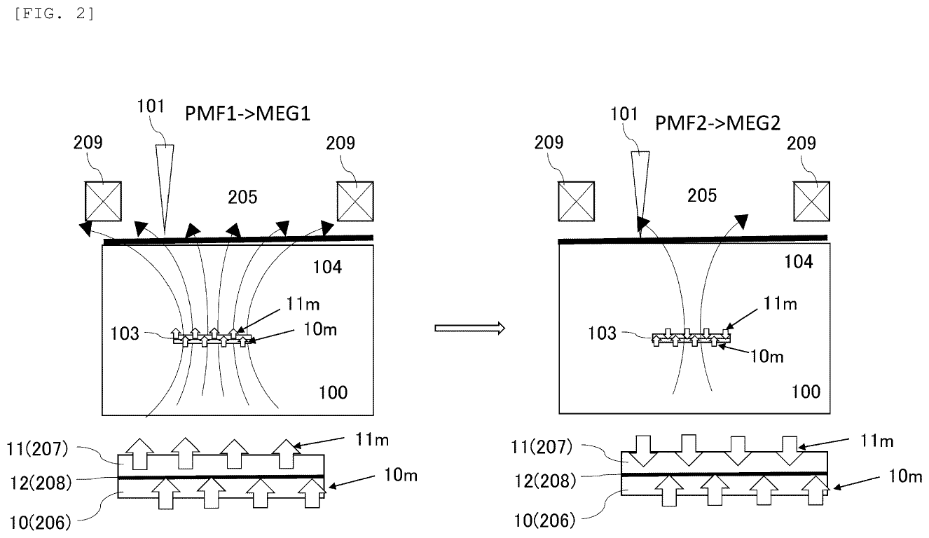

FIG. 2 is a diagram showing importance of a pulse magnetic field according to the present disclosure, and shows a measurement principle when using the pulse magnetic field in a magnetic body inspection using the NVC probe according to the embodiment.

Among the two magnetic layers 10 and 11 of the MTJ 103, the magnetic layer 10 as one of the two layers referred to as a pinned layer 206 is adjacent to the magnetic layer 11 as the other one of the two layers, so that a magnetization direction of the pinned layer 206 is strongly fixed in one predetermined direction (in this example, upward magnetization from the N pole to the S pole), and is fixed so as not to be reversed unless there is an external magnetic field of 1 T level. A magnetization reversal occurs in the magnetic layer 11, as the other one of the two layers, referred to as a free layer 207 provided with respect to the magnetic layer 10 via an insulating layer 208 such as MgO by an external magnetic field of about 0.1 T. If a magnetization direction of the free layer 207 is controlled by applying a pulse magnetic field of about 0.1 T to 1 T before the measurement (in this example, the magnetization direction of the free layer 207 is changed from an upward magnetization direction to a downward magnetization direction), the magnetization of the magnetic layer 10 and the magnetization of the magnetic layer 11 can be individually inspected.

That is, as shown in a first pulse magnetic field applying process (first applying step) PMF1 in FIG. 2, first, a large pulse magnetic field that causes the magnetization of the free layer 207 and the magnetization of the pinned layer 206 to be oriented in a same direction (in this example, both the magnetization direction 10m of the magnetic layer 10 and the magnetization direction 11m of the magnetic layer 11 are the upward magnetization directions) is applied to the magnetic layers 10 and 11 using a pulse magnetic field applying coil 209. When the leakage magnetic field 205 on the wafer 100 is measured after the pulse magnetic field is applied by the first pulse magnetic field applying process PMF1, a large magnetic field is detected (first inspection step MEG1).

Thereafter, as shown in a second pulse magnetic field applying process (second applying step) PMF2 in FIG. 2, a pulse magnetic field corresponding to a magnitude between coercive forces of the pinned layer 206 and the free layer 207 is applied in a direction opposite to the above. Accordingly, only the magnetization of the free layer 207 is reversed (the magnetization direction 11m of the magnetic layer 11 is reversed to the downward magnetization direction), and is oriented in an opposite direction to that of the pinned layer 206 (the magnetization direction 10m of the magnetic layer 10 and the magnetization direction 11m of the magnetic layer 11 are opposite magnetization directions). Thereafter, the same measurement is performed (second inspection step MEG2). At this time, if the magnetization of the two magnetic layers 10 and 11 is normal, the magnetization of the magnetic layer 10 and the magnetization of the magnetic layer 11 cancel each other out, and the leakage magnetic field 205 from the surface of the wafer 100 becomes almost zero. The first pulse magnetic field applying process PMF1 and the second pulse magnetic field applying process PMF2 can be collectively regarded as an applying step. The first inspection step MEG1 and the second inspection step MEG2 can be collectively regarded as a detection step.

In the measurement of the second pulse magnetic field applying process PMF2, if the magnetization of the free layer 207 is damaged and reduced, the magnetization of the pinned layer 206 exceeds the magnetization of the free layer 207, and thus the slight leakage magnetic field 205 is detected, which is in the same direction as the measurement of the leakage magnetic field at a first time (after the application of the first pulse magnetic field applying process PMF1). Conversely, if the magnetization of the pinned layer 206 is damaged, the reversed magnetization of the free layer 207 exceeds the magnetization of the pinned layer 206, and thus the leakage magnetic field 205 in a direction opposite to that of the measurement of the leakage magnetic field at the first time (after the application of the first pulse magnetic field applying process PMF1) is detected.

As described above, soundness of the magnetization of each of the two magnetic layers 10 and 11 can be accurately inspected by measuring an output magnetic field in a parallel state (state before a change of the magnetization of the free layer 207) or an antiparallel state (state after a change of the magnetization of the free layer 207) of the magnetization of the two magnetic layers 10 and 11 by applying the two times of the pulse magnetic field (the first pulse magnetic field applying process PMF1 and the second pulse magnetic field applying process PMF2) and comparing two measurement results. That is, it is possible to configure a system of an inspection device capable of comprehensively inspecting a magnitude, stability, ease of writing, and the like of the magnetization of the two magnetic layers 10 and 11. Accordingly, magnetism of each layer of the two-layer magnetic body (magnetic layers 10 and 11) having different coercive forces and constituting the magnetic tunnel junction of the memory cell of the MRAM can be inspected with high accuracy in a state of being covered with a nonmagnetic body (nonmagnetic layer 104) before wiring.

### Embodiment 1

Hereinafter, an embodiment of the invention will be described.

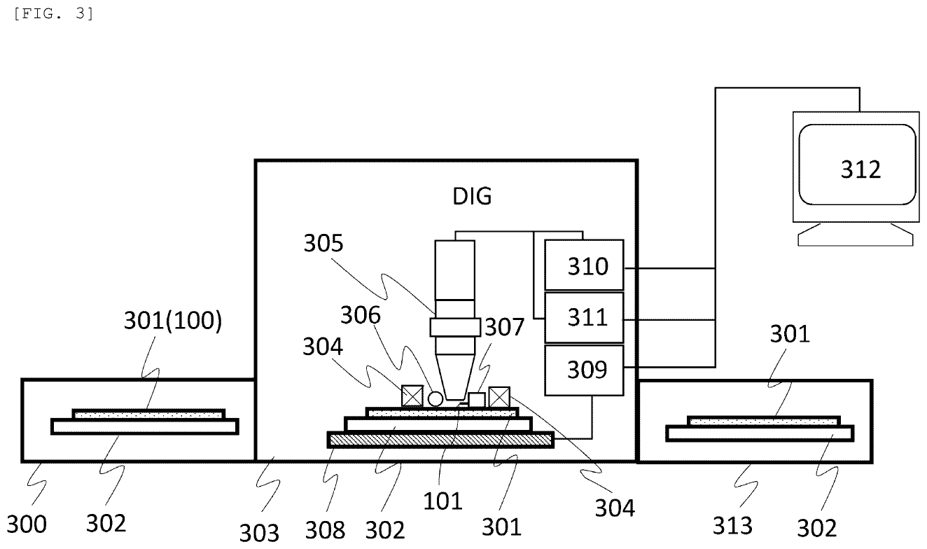

FIG. 3 is a diagram showing an overall configuration of an inspection device according to Embodiment 1, and shows a part of a semiconductor manufacturing system incorporating an inspection device having a disclosed inspection function according to the present embodiment. A wafer 301 (100) of the MRAM which is subjected to etching is mounted on a conveyance holder 302 in a conveyance chamber 300. Thereafter, the wafer 301 is carried to an evaluation chamber 303. The evaluation chamber 303 includes an inspection device DIG. A pulse magnetic field applying coil 304 (209), an objective lens 305 for performing irradiation with a green band laser and for collecting red band fluorescence, a microwave irradiation antenna 306, an NVC probe 101 having an NVC mounted thereon, and a probe holder 307 are mounted on the inspection device DIG. Here, the wafer 301 is moved by a drive stage 308, and the magnetic layers 10 and 11, as the two-layer magnetic body, are set immediately below the NVC probe 101 to perform the inspection. It is possible to improve throughput of the inspection by mounting a plurality of the NVC probes 101 and the probe holders 307 on the inspection device DIG. The inspection device DIG further includes a drive stage control device 309, a green band laser light source 310, a red band fluorescence detector 311, a control system (control device) 312, and the like, and the drive stage control device 309, the green band laser light source 310, and the red band fluorescence detector 311 are controlled by the control system (control device) 312 to perform the inspection. After the inspection is ended, the wafer 301 and the conveyance holder 302 are conveyed to another conveyance chamber 313 for a next process.

That is, a scanning probe microscope as the inspection device DIG including the NVC probe 101 processed into a probe shape is incorporated in a part of the semiconductor manufacturing system. The scanning probe microscope as the inspection device DIG includes the sample stage (sample placement stage, drive stage) 308 on which the sample (wafer 301 (100)) having the two-layer magnetic body (magnetic tunnel junction: MTJ 103) formed of the magnetic bodies 10 and 11 having different coercive forces and manufactured in a semiconductor manufacturing process is placed and set, the microwave irradiation antenna 306 that irradiates the NVC probe 101 with microwaves, the green band laser light source 310 that emits a green band laser to irradiate the NVC probe 101, a red band fluorescence detector 311 that detects red band fluorescence from the NVC probe 101, the pulse magnetic field applying coil 304 (209) that applies the pulse magnetic field to the sample 100, a pulse magnetic field generation device (not shown) that generates the pulse magnetic field to be applied to the pulse magnetic field applying coil 304 (209), and a microwave generation device (not shown) that generates the microwaves to be applied to the microwave irradiation antenna 306. In measurement data of the leakage magnetic field, the inspection device DIG measures the leakage magnetic field on the surface of the sample 100 immediately after the pulse magnetic fields are applied (the first pulse magnetic field applying process PMF1 and the second pulse magnetic field applying process PMF2), and inspects the magnetism of each of the magnetic layers 10 and 11 of the sample 100 by a plurality of measurements in which a plurality of pulse magnetic fields with different conditions are applied.

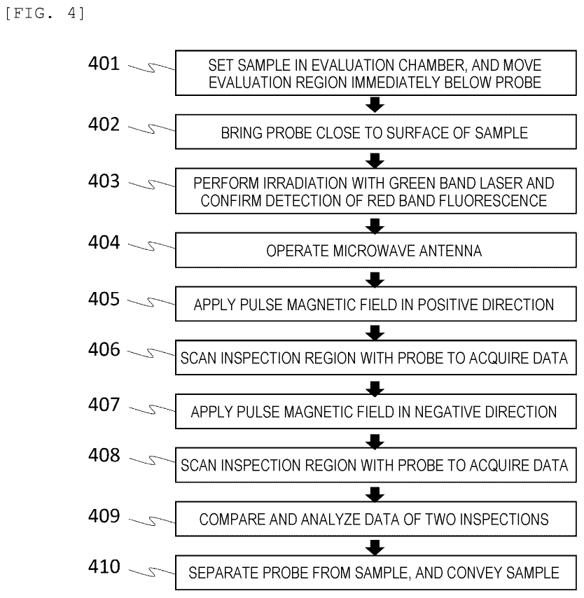

A flowchart of an inspection process in the evaluation chamber 303 will be described with reference to FIG. 4. FIG. 4 shows a flowchart of the inspection according to Embodiment 1. Each step (401 to 410) shown in FIG. 4 will be described.
401: First, the wafer (sample) 301 is set on the drive stage 308 of the evaluation chamber 303. The drive stage 308 moves an inspection region of the wafer 301 to be inspected immediately below the probe 101.
402: Then, the probe 101 is brought close to the surface of the sample 301.
403: Thereafter, a measurement system capable of performing irradiation with the green band laser and detecting the red band fluorescence is confirmed.
404: Thereafter, the microwave generation device operates the microwave antenna 306 to irradiate the probe 101 with microwaves.
405: Thereafter, the pulse magnetic field applying coil 304 (209) is driven by the pulse magnetic field generation device, and the pulse magnetic field is applied from the pulse magnetic field applying coil 304 (209) to the inspection region of the wafer 301 in a positive direction (first pulse magnetic field applying process PMF1). Here, an example of the application of the pulse magnetic field using the pulse magnetic field applying coil 304 is described, but a method of bringing a magnet including an iron core close to the wafer 301 may be used. Alternatively, a method of bringing a permanent magnet material close to the wafer 301 may be used. In this case, in order to individually control the magnetization of the magnetic layer 10 and the magnetization of the magnetic layer 11, it is preferable to prepare two or more types of permanent magnets having different output magnetic fields and polarities, for example, by changing materials. In this process, by applying a magnetic field of several 100 mT, the magnetization of the pinned layer 206 (10) and the magnetization of the free layer 207 (11) are oriented in the same direction.
406: Thereafter, the magnetic field applied to the wafer 301 is returned to zero, and the inspection region is scanned by the NVC probe 101 to acquire inspection data of a first time (first inspection step). At this time, the NVC probe 101 detects the leakage magnetic field by slightly moving the wafer 301 while detecting the magnetic field 205 leaking from the two magnetic layers 10 and 11 of the MRAM. A method of acquiring the inspection data may be creation of a magnetic field distribution image by two-dimensional mapping, creation of a magnetic field distribution line by one-dimensional mapping, or a one-point inspection of a magnitude of the magnetic field by point analysis. This data acquisition method also relates to the throughput of the inspection.
407: After the acquisition of the inspection data of the first time, the pulse magnetic field applying coil 304 (209) is driven by the pulse magnetic field generation device, and the pulse magnetic field is applied from the pulse magnetic field applying coil 304 (209) to the inspection region of the wafer 301 in a negative direction (second pulse magnetic field applying process PMF2). The magnetic field in this case reverses only the magnetization direction of the free layer 207 (11).
408: Thereafter, the magnetic field applied to the wafer 301 is returned to zero, and the inspection region is scanned again by the NVC probe 101 to acquire inspection data of a second time (second inspection step).
409: The magnetization of two magnetic layers 10 and 11 are inspected by comparing and analyzing the inspection data of the first time and the second time with the application of the pulse magnetic field (405 and 407) interposed therebetween.
410: After the inspection is completed, the probe 101 is separated from the sample 301, and the drive stage 308 moves another inspection region of the wafer 301 immediately below the probe 101. In this manner, the magnetization of the MTJ on the wafer 301 is sequentially inspected. After an entire region as an inspection target on the wafer 301 is inspected, the wafer 301 is moved to another chamber.

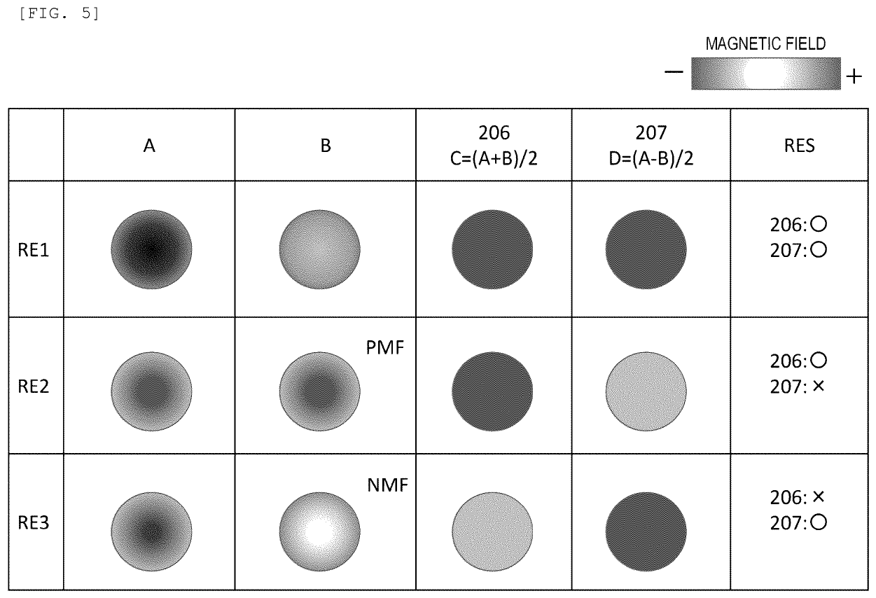

Next, an example of acquired data and a display method thereof will be described with reference to FIG. 5. FIG. 5 shows data acquired in the inspection according to Embodiment 1 and analysis examples. As shown in an upper right part of a table, a magnitude of the magnetic field detected by the probe or a magnitude of the magnetization of each layer is displayed in a gray scale, and the positive direction is black and the negative direction is white. Here, it is assumed that the probe 101 detects the magnetic field in the vertical direction of the surface of the sample 301 (100) and the leakage magnetic field 205 (105) is two-dimensionally mapped. In FIG. 5, magnetization states of the respective layers of the magnetic layers 206 and 207 when the pinned layer 206 and the free layer 207 of the circular MTJ 103 are viewed from above are reconstructed and displayed for each layer. In measurement data (A) when the pulse magnetic field is positively applied (the first inspection step MEG1 after the first pulse magnetic field applying process PMF1), it is assumed that the magnetization of the pinned layer 206 and the magnetization of the free layer 207 are oriented in the same direction, but a magnetic field is detected in a concentric manner, with the maximum at a center portion and gradually decreasing in an inspection region RE1. In measurement data (B) when the pulse magnetic field is negatively applied (the second inspection step MEG2 after the second pulse magnetic field applying process PMF2), it is assumed that the magnetization directions of the pinned layer 206 and the free layer 207 are opposite to each other and the output magnetic fields of the pinned layer 206 and the free layer 207 cancel each other, but the leakage magnetic field is also almost zero. By performing magnetization reconstruction calculation for each layer based on the measurement data of (A) and (B) taking into account the measurement conditions and the shape of MTJ 103, it is assumed that both the pinned layer 206 and the free layer 207 have sound magnetization, and as a result RES, an evaluation of the inspection region RE1 is both the pinned layer 206 and the free layer 207 being good (o). Here, assuming an extremely rough image, magnetization (C) of the pinned layer 206 can be calculated based on a sum of the measurement data (A) and the measurement data (B) as C=(A+B)/2. Magnetization (D) of the free layer 207 can be calculated based on a difference between the measurement data (A) and the measurement data (B) as C=(A−B)/2. Specifically, the magnetization of each layer should be calculated by reconstruction simulation or the like.

In addition, in an inspection region RE2, in the measurement data (A), similarly to the inspection region RE1, a magnetic field is detected, the magnetic field being maximum at the center portion and gradually decreasing in the concentric manner. However, as compared with the inspection region RE1, a magnitude of the magnetic field is slightly smaller. On the other hand, in the measurement data (B), a value of the magnetic field is almost zero in the center portion, but a slight magnetic field in the positive direction is detected in an outer peripheral portion of a circle. That is, in the measurement data (B) in which the magnetization of the pinned layer 206 and the magnetization of the free layer 207 should be canceled in the opposite directions, the magnetization is not canceled in a peripheral portion. Since the leakage magnetic field is in the positive direction (positive magnetic field PMF), it is understood that the magnetization of the pinned layer 206 is detected. That is, a situation can be estimated in which the magnetization of the pinned layer 206 cannot be canceled since magnetization having a sufficient magnitude is not generated in the outer peripheral portion of the free layer 207. The table shows the magnetization of the pinned layer 206 and the magnetization of the free layer 207 actually reproduced by a reconstruction program, and as the result RES, the pinned layer 206 is good (o) and the free layer 207 is bad (x).

In addition, in an inspection region RE3, in the measurement data (A), similarly to the inspection region RE2, a magnetic field is detected, the magnetic field being maximum at the center portion and gradually decreasing in the concentric manner. However, a magnitude of the magnetic field is slightly smaller than that of the inspection region RE1. On the other hand, in the measurement data (B), a magnetic field in the negative direction is slightly detected in a center portion of the circle. This is because that the magnetization of the pinned layer 206 and the magnetization of the free layer 207 are not canceled in (B) in which the magnetization of the pinned layer 206 and the magnetization of the free layer 207 should be canceled in the opposite directions. The leakage magnetic field is in the negative direction (negative magnetic field NMF), and therefore, it is understood that the magnetization of the free layer 207 is detected. That is, a situation can be estimated in which the magnetization of the free layer 207 cannot be canceled since the magnetization having a sufficient magnitude is not generated in the pinned layer 206. The table shows the magnetization of the pinned layer 206 and the magnetization of the free layer 207 actually reproduced by the reconstruction program, and as the result RES, the pinned layer 206 is bad (x) and the free layer 207 is good (o). The magnetization of the pinned layer 206 and the magnetization of the free layer 207 can be accurately inspected by the two measurements of the measurement data (A) and the measurement data (B) and analysis thereof as described above.

It is also possible to evaluate stability of the MTJ 103 by performing such an inspection a plurality of times at the same position with a time interval after the pulse magnetic field is applied. In particular, in the second inspection step MEG2, it is expected that the magnetization of the pinned layer 206 and the magnetization of the free layer 207 are antiparallel to each other, which may cause energetic instability, and thus, it is expected that a stability inspection for confirming that the result does not change even after a lapse of time becomes important.

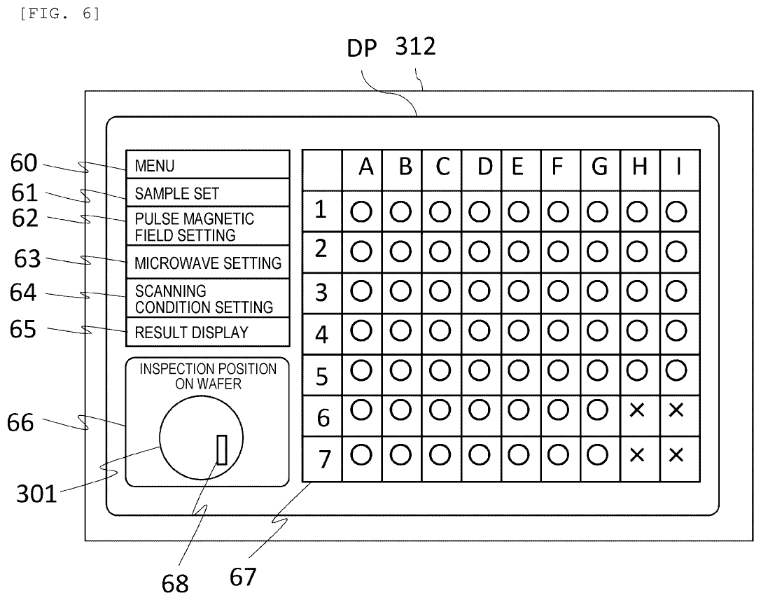

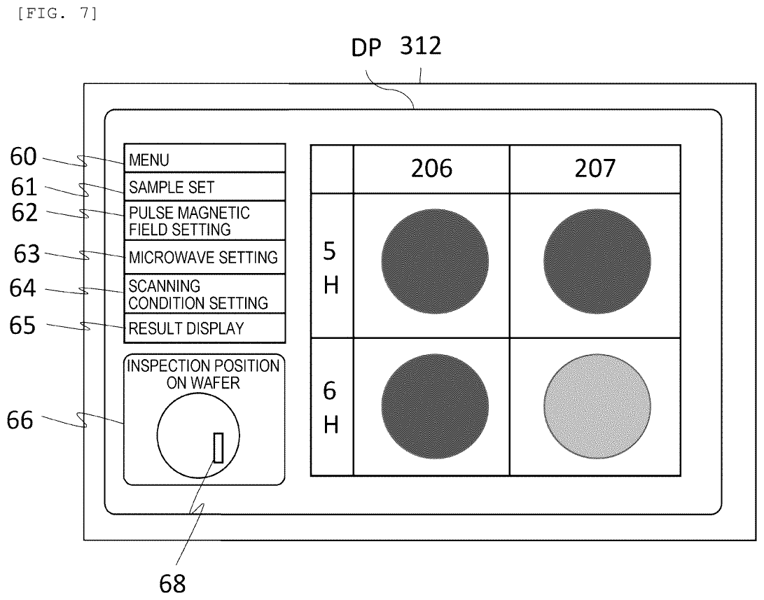

A display example of a display screen DP of the control device 312 according to Embodiment 1 will be described with reference to FIGS. 6 and 7. FIG. 6 shows an example of the display screen of the control device according to Embodiment 1. Here, a list of results at a large number of inspection points is shown. FIG. 7 shows an example of the display screen of the control device according to Embodiment 1. Here, an example of displaying detailed analysis results at a small number of inspection points is shown.

On the display screen DP of the control device 312, an uppermost layer of a menu 60 is listed on a left side, and a “sample set 61” for selecting conveyance and an inspection position of the sample 301, a “pulse magnetic field setting 62” for setting a magnitude and an application time of a pulse magnetic field to be applied before an observation, a “microwave setting 63” for setting an intensity of a microwave to be emitted to the NVC probe 101 and issuing an ON/OFF instruction, a “scanning condition setting 64” for selecting whether to perform the magnetic field detection by the NVC probe 101 in a two-dimensional manner, or in a one-dimensional manner, or to perform the point analysis, setting a time thereof, issuing a measurement start or stop instruction, a “result display 65” for displaying a progress situation and a result of the inspection, an analysis result, and the like are listed on the menu. At a lower left part, a diagram FIG. 66 showing which part in the entire wafer 301 is set as an inspection position 68 is displayed. In the center portion of FIG. 6, an evaluation point list 67 is displayed by the menu of the “result display 65”. Here, inspection results of respective points are shown by defining coordinates on the wafer 301 in the two-dimensional manner using numbers in a vertical direction and alphabets in a horizontal direction. In this table, the evaluation is good (o) in most results, but some defective (x) results are observed in a lower right corner. Further, by clicking this x mark, it is possible to display a detailed situation including whether the defective part is the free layer 206 or the pinned layer 207, or which part is defective. FIG. 7 shows an example of a two-dimensional analysis result displayed in this case. Here, as an example, the inspection results of the magnetization of the free layer 206 or the magnetization of the pinned layer 207 at coordinates 5H and 6H are displayed.

When acquired data is evaluated in this manner, it is effective to make a database of patterns of data indicating a good product or a defective product in advance and determine whether a pattern corresponds to that of the database in order to shorten an analysis time. When there is a pattern that does not correspond to that of the database, the magnetization reconstruction calculation of the MTJ 103 may be performed based on the acquired magnetic field data.

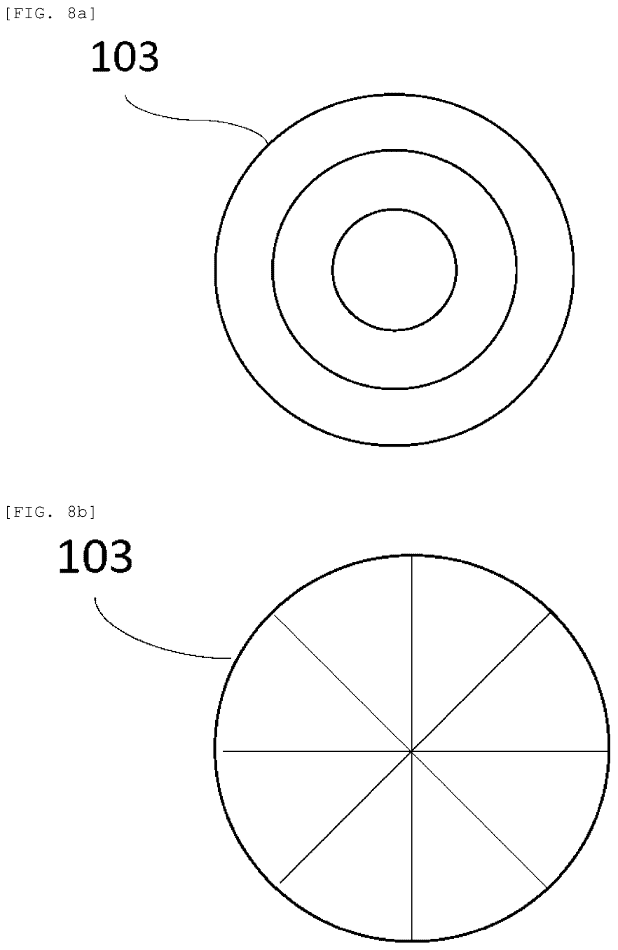

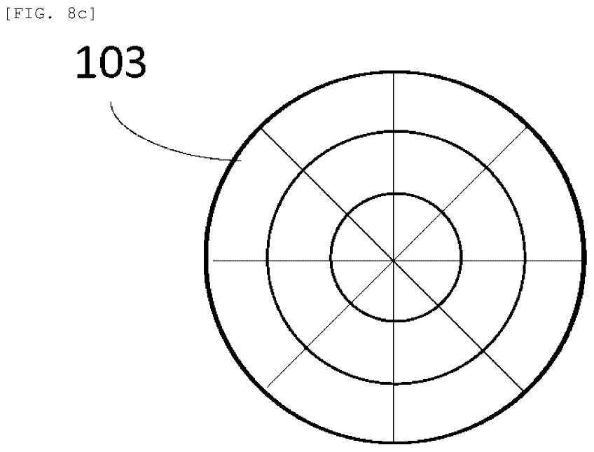

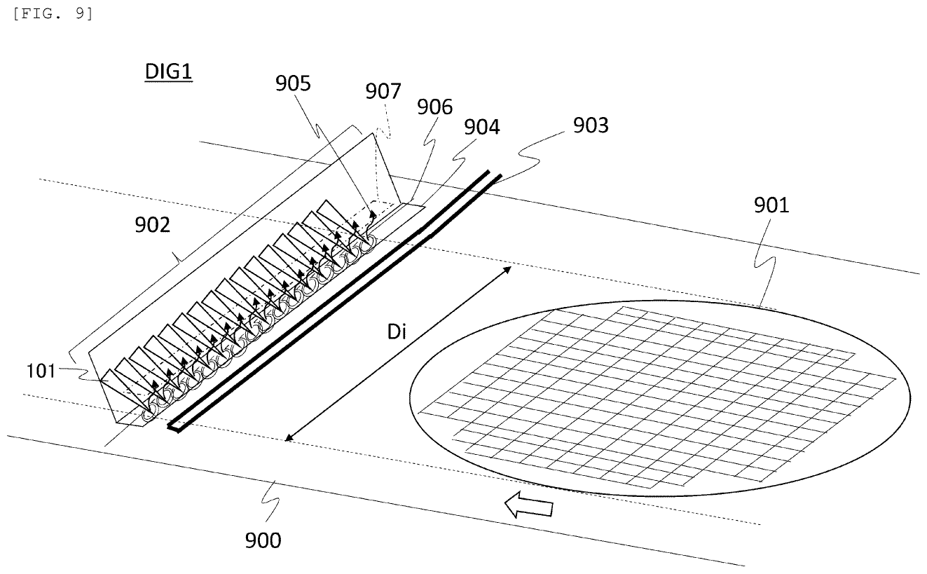

Further, examples of how to obtain a mesh when performing the reconstruction calculation are shown in FIGS. 8a, 8b, and 8c. FIG. 8a shows, in the inspection device according to Embodiment 1, an example of a mesh at the time of magnetic field reconstruction of a MTJ, and shows an example of dividing a bottom surface into concentric shapes. FIG. 8b shows, in the inspection device according to Embodiment 1, an example of the mesh at the time of the magnetic field reconstruction of the MTJ, and shows an example of dividing the bottom surface into sectors with equal interior angles from a center. FIG. 8c shows an example of the mesh at the time of the magnetic field reconstruction of the MTJ, and shows an example in which the concentric circles in FIG. 8a and the sectors divided at interior angles from the center in FIG. 8b are combined.

For example, a method of dividing a bottom surface of the circular MTJ 103 into the concentric shapes (FIG. 8a) and a method of dividing the bottom surface of the MTJ 103 into sectors with equal interior angles from the center (FIG. 8b) are conceivable. In addition, a dividing method may be used in which the concentric circles in FIG. 8a and the sectors divided at equal interior angles from the center in FIG. 8b are combined. In this manner, a region is finely divided, and an inspection result of each region can be displayed. Accordingly, the verification of the inspection of the etching process, the verification of the manufacturing conditions of the MTJ 103, and a feedback to the manufacturing conditions can be immediately performed.

### Embodiment 2

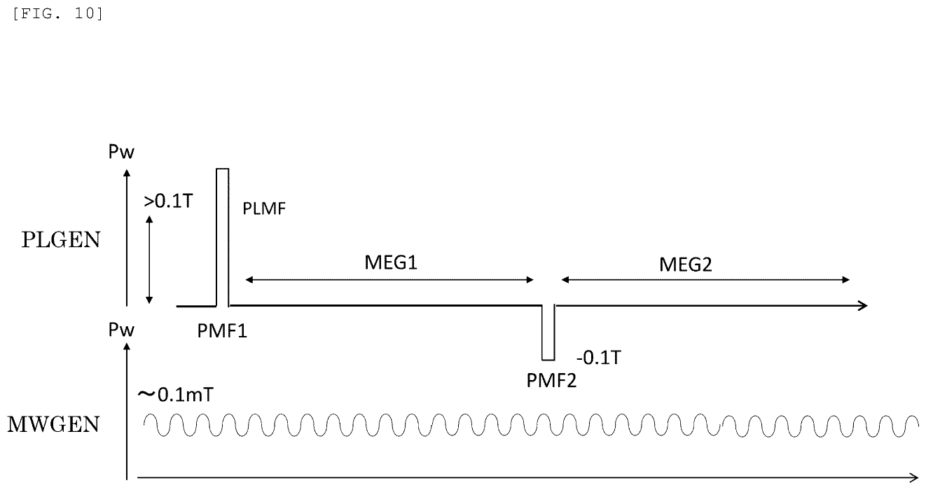

Embodiment 2 will be described with reference to FIG. 9. FIG. 9 shows, in an inspection device according to Embodiment 2, an example of an inspection device in which a plurality of NVC probes are mounted in an array and a microwave antenna is shared by the plurality of probes.

Here, in order to increase the throughput of the inspection, there is shown an inspection device DIG1 capable of simultaneously inspecting a plurality of MTJs 103 formed at different positions in a same (one) wafer 901 (100) using the plurality of NVC probes 101. The inspection device DIG1 includes a conveyance stage 900, a probe array 902, a microwave antenna 903, a green band laser light source 904, a pulse magnetic field applying coil 905, and a red band fluorescence detector 907.

The wafer 901 mounted on the conveyance stage 900 is moved immediately below the probe array 902. In the present embodiment, the microwave antenna 903 has a length equivalent to a diameter Di of the wafer 901 so as to simultaneously irradiate the plurality of NVC probes 101 with microwaves. The green band laser light source 904 is also capable of simultaneously irradiating the plurality of NVC probes 101 with a green band laser. On the other hand, the red band fluorescence detector 907, which is a detection system of red band fluorescence 905, is prepared for each NVC probe 101, so that each MTJ 103 can be inspected. The red band fluorescence detector 907 may be replaced by a detector such as a camera. Further, the microwave antenna 903 and the pulse magnetic field applying coil 906 are provided. In FIG. 9, one microwave antenna 903 is provided for a plurality of probes 101, and one pulse magnetic field applying coil 906 is provided for each probe 101, but the microwave antenna 903 and the pulse magnetic field applying coil 906 may be provided individually for each probe or may be shared by the plurality of probes. As shown in FIG. 9, more MTJ 103 can be inspected in a short time by mounting the plurality of NVC probes 101 and inspection channels (903, 906, 907). That is, an acquisition time of the inspection data of all the MTJs 103 of one wafer 901 can be shortened.

Further, it is expected that the NVC probes 101 have different characteristics. Therefore, it is desired that before the MTJ 103 is actually measured, the characteristic of each NVC probe 101, in particular, responsiveness to the magnetic field is inspected, and results of the inspections are organized as a database before starting the actual measurement.

### Embodiment 3

FIG. 10 shows time dependence of powers supplied to a pulse magnetic field applying coil and the microwave antenna in an inspection device according to Embodiment 3. FIG. 10 shows a graph in which a vertical axis represents a power Pw supplied to the pulse magnetic field applying coils (209, 304, and 906) and the microwave antennas (306 and 903) of the inspection devices (DIG and DIG1) of FIGS. 3 and 9, and a horizontal axis represents a time t. Hereinafter, operations of the pulse magnetic field applying coil 304 and the microwave antenna 306, which serve as representative examples, will be described.

First, a power is supplied from a microwave generation device MMGEN (not shown) to the microwave antenna 306. A microwave emitted from the microwave antenna 306 to the NVC probe 101 has an intensity of a level at which the NVC probe 101 is irradiated with, for example, an AC magnetic field of is about 1 mT. After the irradiation, the microwave continuously emitted until the measurement is completed.

Thereafter, immediately before the first measurement MEG1, a large current flows from a pulse magnetic field generation device PLGEN (not shown) to the pulse magnetic field applying coil 304 for a short time to control the magnetization directions of the pinned layer 206 and the free layer 207 in the MTJ 103 (first pulse magnetic field applying process PMF1). Here, for example, a magnetic field of 0.1 T or more (>0.1 T) is generated. During the subsequent measurement MEG1 performed by the NVC probe 101, the power is not supplied to the pulse magnetic field applying coil 304, and on the other hand, the microwave antenna 306 continues to irradiate the NVC probe 101 with microwaves. When the first measurement MEG1 is completed, as a preprocess of the second measurement MEG2, a power for generating a magnetic field (for example, −0.1 T) having a polarity opposite to a previous polarity, which only changes the magnetization of the free layer 207 of the MTJ 103, is supplied for a short time from the pulse magnetic field generation device PLGEN to the pulse magnetic field applying coil 304 (second pulse magnetic field applying process PMF2). Thereafter, the second measurement MEG2 on the NVC probe 101 is started. During the measurement MEG2, the power is not supplied to the pulse magnetic field applying coil 304, and the microwave antenna 306 continues to irradiate the NVC probe 101 with microwaves. By the two measurements (MEG1 and MEG2), the inspection of the magnetization of the pinned layer 206 and the magnetization of the free layer 207 of one MTJ 103 is completed.

Although the disclosure made by the present inventor has been specifically described above based on the embodiments, it is needless to say that the present disclosure is not limited to the above-described embodiments and examples, and various modifications can be made.

### REFERENCE SIGNS LIST

100: wafer
101: NVC
102: movement direction
103: magnetic tunnel junction (MTJ)
104: nonmagnetic layer
105: leakage magnetic field
200: wafer
201: NVC
202: movement direction
203: magnetic tunnel junction (MTJ)
204: nonmagnetic layer
205: leakage magnetic field
206: pinned layer
207: free layer
208: insulating layer
209: magnetic field applying coil
300: conveyance chamber
301: wafer
302: conveyance holder
303: evaluation chamber
304: pulse magnetic field applying coil
305: objective lens
306: microwave irradiation antenna
307: probe on which NVC is mounted and probe holder
308: drive stage
309: drive stage control device
310: green band laser light source
311: red band fluorescence detector
312: control system
900: conveyance stage
901: wafer
902: probe array
903: microwave antenna
904: green band laser light source
905: red band fluorescence
906: pulse magnetic field applying coil
907: red band fluorescence detector

1. An inspection device comprising:
an NVC probe in which diamond having an NVC is set at a tip, the NVC being a composite impurity defect formed of a pair of nitrogen substituting for carbon in a diamond lattice and a vacancy from where a carbon atom adjacent to the substitution nitrogen is removed; and
a pulse magnetic field applying unit, wherein
the pulse magnetic field applying unit executes an applying step of applying a pulse magnetic field to a magnetic body in a sample, and
the NVC probe executes a detection step of detecting a magnetic field from the magnetic body when application of the pulse magnetic field by the pulse magnetic field applying unit is stopped.

2. The inspection device according to claim 1, wherein
the magnetic body has a plurality of layers, and
the pulse magnetic field applying unit changes magnetization of at least one of the layers of the magnetic body.

3. The inspection device according to claim 2, wherein
the plurality of layers are two magnetic layers forming a magnetic tunnel junction having an upper surface covered with a nonmagnetic body, and
the pulse magnetic field applying unit applies a magnetic field for changing a magnetization state of one magnetic layer of the two magnetic layers.

4. The inspection device according to claim 3, wherein
in the detection step, the magnetization of the one magnetic layer is inspected using measurement data of a magnetic field detected before a change in the magnetization of the one magnetic layer and measurement data of a magnetic field detected after the change in the magnetization of the one magnetic layer.

5. The inspection device according to claim 4, wherein
the applying step includes
a first applying step of applying the pulse magnetic field from the pulse magnetic field applying unit to the two magnetic layers such that magnetization directions of the two magnetic layers coincide with each other, and
a second applying step of applying a pulse magnetic field from the pulse magnetic field applying unit to the two magnetic layers by changing a direction or a magnitude of the pulse magnetic field applied in the first applying step such that magnetization of the one magnetic layer is changed,
the detection step includes
a first inspection step of measuring a magnetic field from the two magnetic layers by the NVC probe after the first applying step, and
a second inspection step of measuring a magnetic field from the two magnetic layers by the NVC probe after the second applying step, and
the magnetization of each of the two magnetic layers is inspected by analyzing first measurement data obtained in the first inspection step and second measurement data obtained in the second inspection step.

6. The inspection device according to claim 5, wherein
a sum and a difference between the first measurement data obtained in the first inspection step and the second measurement data obtained in the second inspection step are calculated to reconstruct the magnetization of each layer of the two magnetic layers, and the magnetization is displayed for each layer.

7. The inspection device according to claim 3, further comprising:
a plurality of the NVC probes; and
a red band fluorescence detector, wherein
the sample is a wafer including a plurality of the magnetic tunnel junctions, and
in the detection step, the plurality of magnetic tunnel junctions formed at different positions of the same wafer are inspected using the plurality of NVC probes and the red band fluorescence detector.

8. The inspection device according to claim 7, further comprising:
one microwave antenna configured to irradiate the plurality of NVC probes with microwaves, wherein
in the detection step, a measurement is performed while irradiating the plurality of the NVC probes with the microwaves from the microwave antenna.

9. The inspection device according to claim 8, wherein
the pulse magnetic field applying unit includes one pulse magnetic field applying coil, and
the pulse magnetic field applying coil controls the magnetization of the two magnetic layers forming each of the plurality of magnetic tunnel junctions formed at the different positions of the wafer.

10. The inspection device according to claim 9, further comprising:
one green band laser light source configured to irradiate the plurality of NVC probes with a green band laser, wherein
in the detection step, the green band laser light source irradiates the plurality of NVC probes with the green band laser, and the red band fluorescence detector detects red band fluorescence generated from the plurality of NVC probes to measure the magnetization of the two magnetic layers.
